(19) United States
(12) Patent Application Publication
(10) Pub. No.: US 2023/0403031 A1
(43) Pub. Date: Dec. 14, 2023

(54) ENCODING OF POLAR CODES WITHOUT THE USE OF GENERATOR MATRIX

(71) Applicant: CANKAYA UNIVERSITESI, Ankara (TR)

(72) Inventor: Orhan GAZI, Ankara (TR)

(73) Assignee: CANKAYA UNIVERSITESI, Ankara (TR)

(21) Appl. No.: 18/246,684

(22) PCT Filed: Oct. 27, 2020
(86) PCT No.: PCT/TR2020/051006

§ 371 Date: Mar. 27, 2023

(51) Int. Cl. H03M 13/13; H03M 13/00

(52) U.S. Cl. CPC H03M 13/13; H03M 13/6572; H03M 13/6575

(57) ABSTRACT

A novel method for providing encoding of polar codes without the use of generator matrix is proposed.

### CROSS-REFERENCE TO THE RELATED APPLICATION

This application is the national stage entry of International Application No. PCT/TR2020/051006, filed on Oct. 27, 2020, the entire contents of which is incorporated herein by reference.

### TECHNICAL FIELD

In this invention, a novel method for providing encoding of polar codes without the use of generator matrix is proposed.

### BACKGROUND

The encoding operation of the polar codes can be achieved using

x=uG

where u is the information word, x is code-word and G is the generator matrix which is obtained using

G_{N}=B_{N}F^{⊗n}

in which

$$N = {2}^{n} , F = [ \begin{matrix}1 & 0 \\ 1 & 1\end{matrix} ]$$

and B_{N} is calculated using

$${B}_{N} = {R}_{N} ( {I}_{2} ⊗ {B}_{\frac{N}{2}} )$$

### SUMMARY

The present invention is related to encoding of polar codes without the use of generator matrix in order to eliminate the disadvantages mentioned above and to bring new advantages to the related technical field.

This invention proposes a method for the encoding of polar codes without the employment of generator matrix.

Advantageous of the proposed method;
1) The structure of invention is suitable for hardware implementations.
2) It eliminates the storage of generator matrix and saves hardware space.
3) It is suitable for parallel processing operations.
4) The proposed structure can be used as a generic polar encoder structure of all codeword lengths.

It is also possible to generate all the code bits at the same time using the proposed tree-encoding structures in parallel.

One of the aim of propose method that avoids the use of generator matrix, a saving in memory space of FPGA devices is achieved and this reduces the hardware complexity of the polar encoders.

### BRIEF DESCRIPTION OF THE DRAWINGS

The figures have been used in order to further disclose developed encoding of polar codes without the use of generator matrix by the present invention which the figures have been described below.

FIG. 1 Polar encoder for N=4 with discrete memoryless channels.

FIG. 2 Encoding path for the code bit x₀.

FIG. 3 Tree representation of the encoding path for the code bit x₀.

FIG. 4 Encoding path for the code bit x₁.

FIG. 5 Tree representation of the encoding path for the code bit x₁.

FIG. 6 Encoding path for the code bit x₂.

FIG. 7 Tree representation of the encoding path for the code bit x₂.

FIG. 8 Encoding path for the code bit x₃.

FIG. 9 Tree representation of the encoding path for the code bit x₃.

FIG. 10 Generation of code bit x₆.

FIG. 11 Generation of code bit x₁₃.

### DETAILED DESCRIPTION OF THE EMBODIMENTS

The novelty of the invention has been described with examples that shall not limit the scope of the invention and which have been intended to only clarify the subject matter of the invention. The present invention has been described in detail below.

A novel method for encoding of polar codes without the use of generator matrix was presented.

In close future, the telecommunication devices will be upgraded to 5G standard and 5G standard heavily use the digital electronic devices which can be programmed in hardware such as FPGAs. It is vital to use the resources of FPGAs in an efficient manner. The encoding operation of the polar codes can be achieved using

x=uG

where u is the information word, x is code-word and G is the generator matrix. For N=1024, and for full rate encoding operation binary generator matrix of size 1024×1024 is needed and this matrix should be stored in the memory units of the FPGA devices.

This invention proposes a method for the encoding of polar codes without the employment of generator matrix. The proposed method utilizes an n-bit, where n=log₂ N, binary counter and a tree structure involving n levels. Since the propose method avoids the use of generator matrix, a saving in memory space of FPGA devices is achieved and this reduces the hardware complexity of the polar encoders.

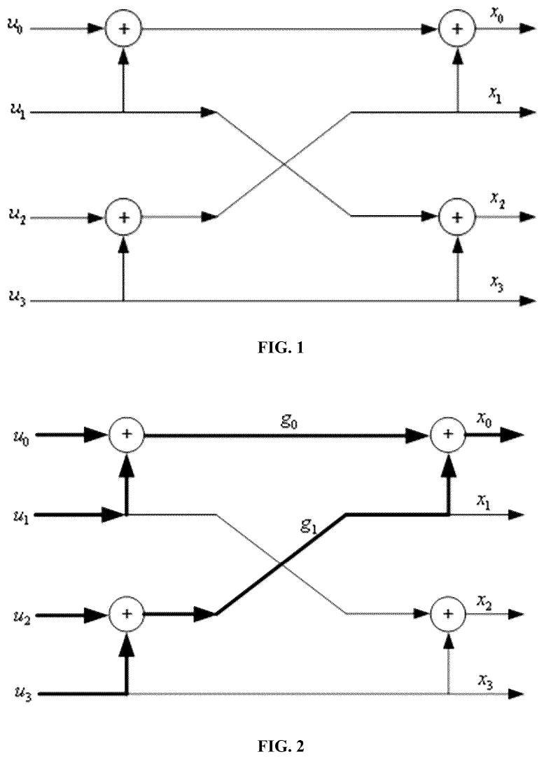

The polar encoder unit for frame length N=4 is depicted in FIG. 1

From FIG. 1, getting of

x₀=u₀⊕u₁⊕u₂⊕u₃

x₁=u₂⊕u₃

x₂=u₁⊕u₃

x₃=u₃

which can be written as

x̅=ū×G

where

x̅=[x₀x₁x₂x₃]ū=[u₀u₁u₂u₃]

and the generator matrix G equals to

$${G}_{4} = [ \begin{matrix}1 & 0 & 0 & 0 \\ 1 & 0 & 1 & 0 \\ 1 & 1 & 0 & 0 \\ 1 & 1 & 1 & 1\end{matrix} ] . \qquad ( 1.2 )$$

The path for the generation of the code bit x₀ is depicted in FIG. 2

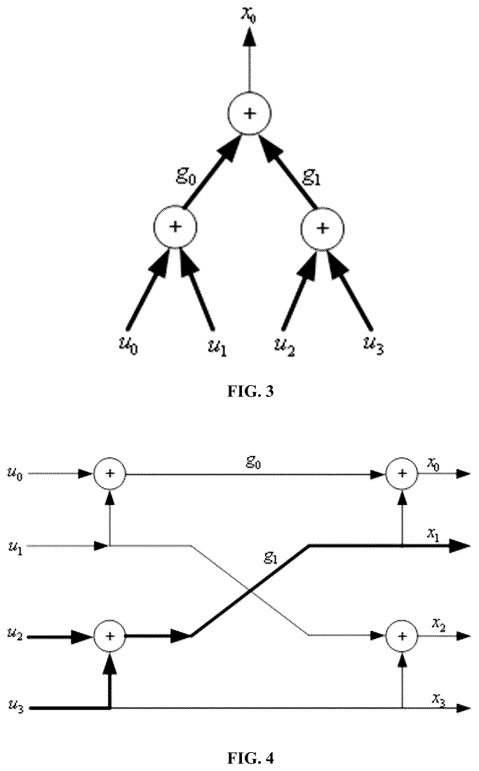

The encoding path shown in FIG. 2 can be drawn as a tree as in FIG. 3 where bold lines indicate the propagation of the bits which contribute to the generation of the code bit x₀.

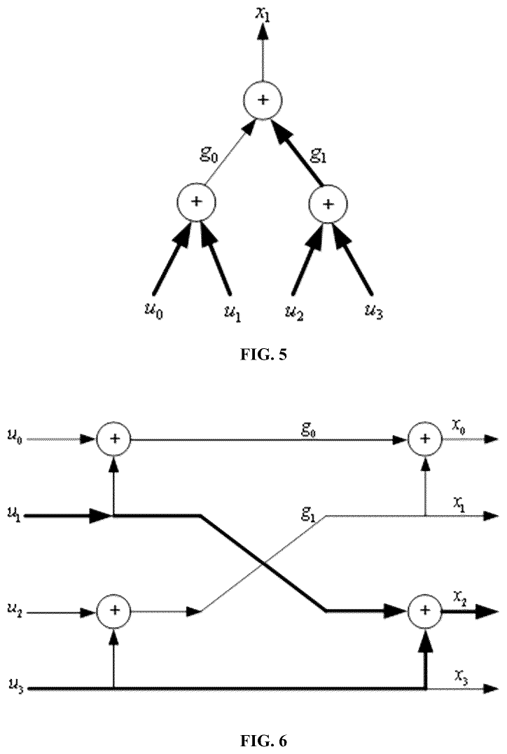

In as similar manner the encoding path for x₁ and its tree representation can be drawn as in FIG. 4 and FIG. 5.

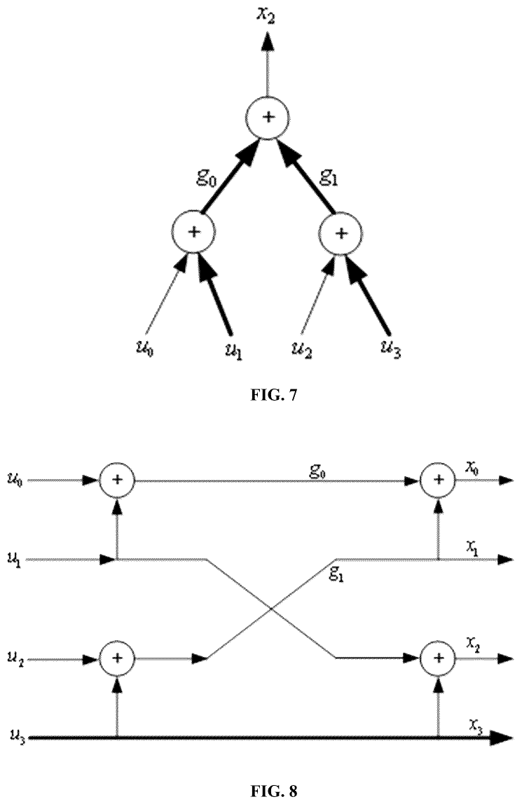

The encoding path for x₂ and its tree representation can be drawn as in FIG. 6 and FIG. 7.

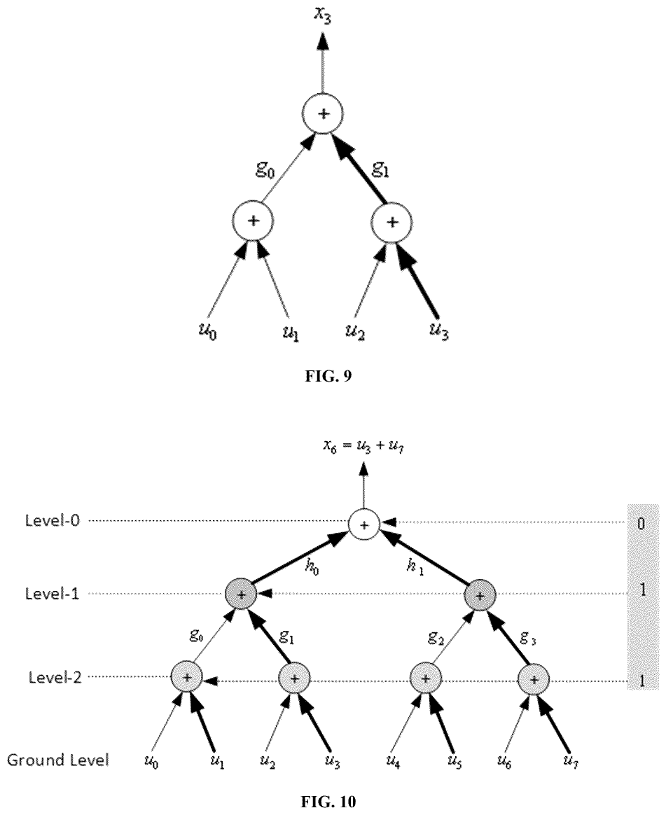

The encoding path for x₃ and its tree representation can be drawn as in FIG. 8 and FIG. 9.

Inspecting the encoding operations in FIGS. 1 to 9 and their trellis representations, we propose the polar encoding without the employment of generator matrix as follows.

Pass-Nodes:

Pass-nodes in encoding tree are defined as the nodes which only take the right incoming input bit from the lower layer.

Sum-Nodes:

Sum-nodes in encoding tree are defined as the nodes which produce the mod−2 sum of the left and right incoming input bits from the lower level in the tree structure.

An n-bit counter is used in for the encoding operation. The ‘1’s in the n-bit counter indicate the levels which include pass nodes, and 0's in the n-bit counter indicate the levels which include sum-nodes. The n-bit counter is initialized to all zero tuple, and it is incremented at the calculation of each succeeding code-bit. The least significant-bit of the counter indicates the top-level in the tree structure, and the most significant-bit of the counter indicates the bottom level of the tree structure.

For instance, in FIG. 10 for N=8, the generation of the code bit x₆ is illustrated. The counter has the value of 011 and, the ‘1’s in the counter indicates the levels 1 and 2 where the nodes are pass-nodes. The propagating signals are shown using bold arrows.

A method of encoding of polar codes, the method comprising;
1. Initializing of n-bit counter, where n=log₂(N) in which N is the codeword length, counter to all zeros and setting of k=0 where k is the index of the code-bit to be generated as index of code-bit xₖ,
2. Forming the tree structure consisting of n levels such that the bottom level consisting of N nodes, and the top level consisting of a single node,
3. Generating of the code-bit xₖ, k=0 . . . N−1, and where n-bit counter has the binary equivalent of k.
4. Assigning the counter bits to the levels of the tree in a vertical downward manner such that the least significant bit of the counter points to the top level, i.e., level-0, and the most significant bit of the counter points to the level-(n−1).
5. The nodes of those levels corresponding to the positions of ‘1’s of the counter (Deciding of the levels corresponding to positions of ‘1’s in the counter) are labeled as the pass-nodes, and the other levels are labeled as sum-nodes.
6. Starting from the lowest level above the ground level in the three structure, i.e., starting from level-(n−1), XOR the bit pairs coming from the nodes of predecessor level if the level has label ‘0’, otherwise, just pass the incoming bit of right node to the upper-level (from the predecessor level to the current level), and repeat this process till the top-most level and obtaining of the code bit xₖ.
7. If=N−1, terminating the method, otherwise, incrementing the k value and returning to step 3.

According to method, where n-bit counter has the binary equivalent of k in step ii, where k is the index of the code-bit to be generated.

### Example

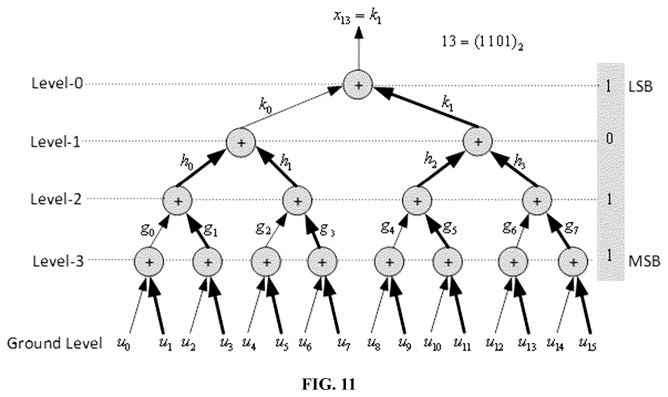

For N=16, the generation of the code bit x₁₃ is illustrated in FIG. 11, where the 4-bit binary counter has the value “1101” whose decimal equivalent is 13.

For N-bit codewords, the encoding algorithm and its graphical illustration via an example are given.

In addition, if we have an N-bit tree encoder structure, the other encoder structure involving N/2 bits can be obtained considering only the left-part of the tree structure, and this logic can be carried on left-part to obtain the tree-encoder structure involving N/4 bits and so on.

Fast Encoding Using Parallel Tree-Encoding Structures:

It is also possible to generate all the code bits at the same time using the proposed tree-encoding structures in parallel. Since, we know the counter values, and many of the tree-encoding structures can run in parallel and encoding operation can be completed by all parallel units at the same time. This approach reduces the encoding latency significantly; however, the hardware complexity increases.

1. A method of encoding of polar codes, comprising:
i. initializing of n-bit counter, where n=log₂(N) in which N is the codeword length, to all zeros and setting of k=0 where k is the index of the code-bit to be generated as index of code-bit xₖ,
ii. forming the tree structure consisting of n-levels as the bottom level consisting of N nodes and the top level consisting of a single node,
iii. generating of the code-bit xₖ, k=0 . . . N−1, and n-bit counter having the binary equivalent of k,
iv. assigning the counter bits to the levels of the tree,
v. the least significant bit of the counter pointing to the top level as level-0,
vi. assigning the other bits to the levels in a downward manner as the most significant bit of counter pointing to the level-(n−1),
vii. deciding of the levels corresponding to positions of ‘1’s in the counter,
viii. labeling those levels corresponding to the positions of ‘1’s of the counter as the pass-nodes, and labelling of the other levels as sum-nodes,
ix. starting from lowest level above the ground level in the tree structure as starting from level-(n−1),
x. if the level has label ‘0’, taking the XOR of bit pairs coming from the nodes of the predecessor level, otherwise, just passing the incoming bit of right node from the predecessor level to the current level, and repeating of this process till the top-most level and obtaining of the code-bit xₖ,
xi. if=N−1, terminating the method, otherwise, incrementing the k value and returning to step iii.

2. The method according to claim 1, where the n-bit counter has the binary equivalent of k in step ii, where k is the index of the code-bit to be generated.
